(19) United States
(12) Patent Application Publication
(10) Pub. No.: US 2012/0190555 A1
(43) Pub. Date: Jul. 26, 2012

(54) CONSTRUCTION OF SUPERCONDUCTING MULTI-CORE BILLET AND METHOD FOR MANUFACTURING SUPERCONDUCTING MULTI-CORE WIRES

(75) Inventors: Takaaki SASAOKA, Tsuchiura (JP); Morio KIMURA, Kasumigaura (JP); Yoshihiro SAKURAI, Tsukuba (JP); Katsumi MIYASHITA, Tsuchiura (JP); Hiroshi KOTOU, Tsuchiura (JP); Youichi SUZUKI, Ishioka (JP)

(73) Assignee: HITACHI CABLE, LTD., Tokyo (JP)

(21) Appl. No.: 13/353,927

(22) Filed: Jan. 19, 2012

(30) Foreign Application Priority Data
Jan. 20, 2011 (JP) 2011-009669

(51) Int. Cl. H01F 6/00; H01L 39/24; H01L 39/08; B32B 3/10

(52) U.S. Cl. 505/230; 505/150; 505/433; 335/216; 29/599; 428/596

(57) ABSTRACT

A physical construction of a superconducting multi-core billet is provided together with a method for manufacturing a superconducting multi-core wire to offer reduction of manufacturing time (cost) and low frequency of occurrence of wire break during diameter-reduction drawing. The superconducting multi-core billet by the present invention has such a construction that a plurality of vertical holes are made in a billet 2 of copper or copper alloy of circular cross-section; that the vertical holes are filled with a superconducting material 4 comprised of NbTi; that a copper-volume ratio, which is a ratio of the copper or the copper alloy to NbTi in volume, is not smaller than four; that the plurality of vertical holes are made in the billet so that each of the vertical holes will be arrayed at an equal spacing on each of two inner and outer layers concentric circles.

### TECHNICAL FIELD

The present invention relates to a physical construction of a superconducting multi-core billet and a method for manufacturing the superconducting multi-core wires, wherein the invented construction of the superconducting multi-core billet permits superconducting material composited therein to be worked into filaments having a satisfactory shape.

### BACKGROUND OF THE INVENTION

Superconducting wires have been applied to various fields because of their capability of carrying large current without loss of electrical power or capability of generating ferro-magnetic field. For example, the application may be found in technology advance in the fields of energy-saving system development by introducing superconducting system into electric power systems such as generators and power transmission cables, in new energy system development such as nuclear fusion and magnetohydrodynamics (MHD) generation, and in new technique development in use of ferro-magnetic field such as high-energy accelerators and magnetic resonance imaging (MRI) for medical application.

The superconducting wire technology has been actively developed to advance such superconductivity application technologies. Until now, niobium-titanium (NbTi) alloy group wires has been developed for a magnetic field below 8T or 9T and niobium-tin (Nb₃Sn) compound group wires or vanadium-gallium (V₃Ga) compound group wires for a magnetic filed over such intensity.

These superconducting wires have such a construction that a number of superconducting filaments having a diameter of several ten micro-meter or smaller are embedded in a matrix of metal having an excellent heat conductivity like copper, wherein the material of the superconducting filament is for example NbTi or Nb₃Sn. Superconducting wires of this type of construction are called fine-multi-core wires.

The following is a rough explanation about a method for manufacturing a superconducting wire that uses NbTi alloy as its superconducting filament (refer to Non-patent Literature of “Superconductivity Engineering, Revised edition”, Ohmsha, Ltd., pp 74-76, (1988)). First, NbTi alloy is cold worked into a round rod. The rod is then inserted into a copper tube followed by an area-reduction process to obtain a single-core wire. And then, the single-core wire is cut into appropriate lengths. A number of single-core wires thus cut are packed in a copper container, which undergoes air-evacuation followed by lid-welding to seal to form a composite billet. Thereafter, the composite billet undergoes extrusion process and area-reduction process repeatedly until a desired composite wire is obtained. To manufacture a large current capacity wire, it is feasible to pack a number of composite wires thus obtained into another copper tube followed by another area-reduction process. In general, the critical current density of the NbTi alloy wire greatly increases depending on the combination conditions of a heavy-working (area-reduction rate is 10⁴ or more) with aging treatment (thermal treatment at 350 to 450° C.). Therefore, the fine-multi-core wire is usually obtained by applying multiple aging treatments with cold working followed by twisting process.

The most important process in manufacturing the superconducting wire is the manufacturing of the composite billet by packing a number of single wires of copper (Cu), copper/niobium-titanium (Cu/NbTi), or copper/niobium (Cu/Nb) in the copper container. This process almost finalizes the shape of the fine-multi-core wire. Therefore, it is not an exaggeration to say that the finish quality of the process will control the superconductive properties of the wire.

In the above-stated practice however, the composite billet is manufactured by manual insertion of single-core wires into the copper container mobilizing many hands, because the single-core wires cut into proper lengths for insertion count from several ten reaching one thousand and several hundred where the count is great. Therefore, much manpower and man-hour were unavoidably consumed to satisfy requirements for processing accuracy such as linearity of the single-core wire resulting in increased manufacturing cost.

There is another problem in the conventional practice in that the packing density of the single-core wires had a limit. This means that accommodating more increased number of single-core wires and fine-sizing the superconducting filament are of importance to respond the future demand for more enhanced performance of superconducting wires. For this, it becomes necessary in manufacturing the composite billet to increase the number of the single-core wires to be packed in the copper container, or instead, to increase the number of repetition of compositing process. Therefore, a good workability has been desired because the conventional practice had a limit.

To increase the number of the single-core wires to be accommodated means that the distance between the superconducting filaments in the fine-multi-core wire will be made shorter more than before. Therefore, the properties are degraded because of increase in the alternating-current loss attributable to the superconductive coupling that appears in a part of or over almost all the superconducting filaments due to physical coupling and proximity effect. Thus, when a simple method other than the packing of single-core wires in the copper container in the manufacturing the composite billet is practicable, it becomes feasible not only to simplify the manufacturing method and to cut manufacturing cost but also to improve the superconductive properties.

JP 54-22758 A, JP 2868966 B2 and JP 3445307 B2 describe improved methods for manufacturing a composite billet. According to their descriptions, a billet for extrusion is manufactured through the processes of providing a pile of several number of copper blocks each having a plurality of vertical holes thereon, inserting rods of superconducting material into holes of the copper blocks in the pile, placing lids on both ends of the copper block, and welding the periphery of the pile of copper blocks with electron beam in vacuum.

In the art that JP 2868966 B2 describes, the superconducting billet is formed by making holes on a round copper rod, wherein the numbers of the holes are, for example, 337, 313, 73, 246, 222, and 232, and inserting superconducting material such as niobium (Nb) rod in such holes. Thereafter, the superconducting billet so formed undergoes hot extrusion, drawing, and heat treatment followed by diameter-reduction to manufacture the superconducting multi-core wire having a predetermined finish diameter of wire.

In the art that JP 3445307 B2 describes, the superconducting billet is formed by making holes on a round copper alloy rod, wherein the numbers of holes are 19 and 37, and inserting superconducting material such as Nb rod in such holes. Thereafter, the superconducting billet so formed undergoes extrusion and drawing. The drawn billet is cut and fabricated within a copper tube to form a superconducting multiple billet. The multiple billet so fabricated undergoes extrusion and drawing to manufacture the superconducting multi-core wire.

Usually, holes are arranged so that the interstice between holes will be given the maximum separation. This is because the larger interstice eases the boring work.

The superconducting multi-core wire of the above-stated style undergoes insulating process to form a superconducting winding wire and then wound into a coil to be fabricated into a superconducting magnet, the magnetic field of which is controlled by passing current. In the coiling process in manufacturing a superconducting magnet, a highly accurate technique is required in terms of coiling position and coiling tension. Positional deviation while coiling is a serious problem with respect to the distribution of magnetic field. If uneven-winding problem in coiling operation occurs, such problem will cause the thermal runway (hereinafter referred to as quenching) of the superconducting magnet at currents below the predetermined value. The cause of the quenching of superconducting magnet includes perturbation of coiled wires due to electromagnetic force and instability of the magnetic field. It is thought that the occurrence of the quenching of equipment in actual operation is attributable mostly to the perturbation of coiled wires.

### SUMMARY OF THE INVENTION

The conventional arts stated above however have had problems as described below.

The art described in JP 54-222758 A needs multiple times of electron beam welding in vacuum and therefore the manufacturing process for that was complicated with increased manufacturing cost. Further, because the contacting area between each of the copper blocks is limited merely to the welding penetration (2 mm), wire break frequently occurred during the subsequent process, namely the area-reduction process.

The frequency of occurrence of wire break being low is desirable. When the billet undergoes usual processing to reach the final diameter of wire, it is preferable that the occurrence of wire breaks is 0.001 break/km or less in terms of the finished wire length.

The art described in JP 2868966 B2 encounters a problem of the number of holes for the round copper rod being large. The number of holes being large increased the manufacturing time (cost). The art described in JP 3445307 B2 makes the fabrication process of the billet for extrusion to have two stages of fabrication steps. Therefore, the manufacturing process such as fabrication was sophisticated with the manufacturing time (cost) increased.

Thus, the technical problems in the above-stated arts are two. One is reduction of the manufacturing time (cost) and the other is prevention of wire break during drawing for diameter-reduction.

First object of the present invention is to provide a physical construction of a superconducting wire that offers reduction of manufacturing time (cost) and low frequency of occurrence of wire break during diameter-reduction drawing, together with providing a method for manufacturing such superconducting wire.

Second object of the present invention is to assure the uniformity of the magnetic field generated by a superconducting magnet. Third object of the present invention is to suppress the quenching of superconducting magnet.

### Means for Solving the Problems

To solve above-stated problems, the present invention provides a superconducting multi-core billet comprised of a copper or copper alloy billet of circular cross-section having a plurality of vertical holes made therein filled with superconducting material comprised of NbTi, wherein a copper-volume ratio, which is a ratio of the copper or the copper alloy therein to NbTi therein in volume, is not smaller than four; the plurality of vertical holes are made in the billet so that each of the vertical holes will be arrayed at an equal spacing on each of two inner and outer layers of concentric circles each of which is concentric with respect to the center of the billet; the number of the vertical holes on the outer layer concentric circle N₁ is an even number not smaller than 16 and not larger than 38; the number of the vertical holes on the inner layer concentric circle N₂ is a number defined as N₁/2, N₁/4, or N₁/8; and the position of the vertical hole on the inner layer concentric circle is the angular-midpoint between the positions of the adjacent vertical holes on the outer layer concentric circle.

The superconducting multi-core billet as defined above can otherwise be characterized in that the number of the vertical holes on the inner layer concentric circle N₂ is a prime number.

The present invention further provides a superconducting multi-core billet comprised of a copper or copper alloy billet of circular cross-section having a plurality of vertical holes made therein filled with superconducting material comprised of NbTi, wherein a copper-volume ratio, which is a ratio of the copper or the copper alloy to NbTi in volume, is not smaller than four; the plurality of vertical holes are made in the billet so that each of the vertical holes will be arrayed at an equal spacing on one layer of concentric circle that is concentric with respect to the center of the billet; and the number of the vertical holes on the concentric circle N is not smaller than 16 and not larger than 57.

The superconducting multi-core billet as defined above is characterized further in that the number of the vertical holes N is a prime number or such a prime number as is not smaller than a number N_{b} that is defined as Nₐ×5, wherein Nₐ is a prime number not smaller than 3 and Nₐ is not equal to N_{b}.

The present invention further provides a method for manufacturing a superconducting multi-core wire, comprising the steps of: boring a plurality of vertical holes in a copper or copper alloy billet of circular cross-section; inserting a round NbTi rod into the vertical holes; vacuum-sealing both ends of the vertical holes with metallic lids; and applying hot extrusion process to the vacuum-sealed billet having the round NbTi rod inserted therein followed by repeated application of drawings and heat treatments, wherein a copper-volume ratio, which is a ratio of the copper or the copper alloy therein to NbTi therein in volume, is not smaller than four; the plurality of vertical holes are made in the billet so that each of the vertical holes will be arrayed at an equal spacing on each of two inner and outer layers concentric circles each of which is concentric with respect to the center of the billet; the number of the vertical holes on the outer layer concentric circle N₁ is an even number not smaller than 16 and not larger than 38; the number of the vertical holes on the inner layer concentric circle N₂ is a number defined as N₁/2, N₁/4, or N₁/8; and the position of the vertical hole on the inner layer concentric circle is the angular-midpoint between the positions of the adjacent vertical holes on the outer layer concentric circle.

The method for manufacturing a superconducting multi-core wire as defined above is further characterized in that the number of the vertical holes on the inner layer concentric circle N₂ is a prime number.

The present invention further provides a method for manufacturing a superconducting multi-core wire, comprising the steps of: boring a plurality of vertical holes in a copper or copper alloy billet of circular cross-section; inserting a round NbTi rod into the vertical holes; vacuum-sealing both ends of the vertical holes with metallic lids; and applying hot extrusion to the vacuum-sealed billet having the round NbTi rod inserted therein followed by repeated application of drawings and heat treatments, wherein a copper-volume ratio of the billet, which is a ratio of the copper or the copper alloy therein to NbTi therein in volume, is not smaller than four; the plurality of vertical holes are made in the billet so that each of the vertical holes will be arrayed at an equal spacing on one layer of concentric circle that is concentric with respect to the center of the billet; and the number of the vertical holes on the concentric circle N is not smaller than 16 and not larger than 57.

The method for manufacturing a superconducting multi-core wire as defined above is further characterized in that the number of the vertical holes N is a prime number or such a prime number as is not smaller than a number N_{b} that is defined as Nₐ×5, wherein Nₐ is a prime number not smaller than 3 and Nₐ is not equal to N_{b}.

The present invention can reduce the manufacturing time (cost) for superconducting multi-core wires because the invention optimizes the number of the vertical holes in the superconducting multi-core billet. Further, defining the number of the vertical holes in the billet to be a prime number disperses the tension eliminating local concentration thereby the wire break during diameter-reduction drawing is suppressed.

Another advantageous effect is that the use of the wires of above-stated construction is a useful technique for improving the uniformity of magnetic field and suppressing quenching of superconducting coil.

### BRIEF DESCRIPTION OF DRAWINGS

FIG. 1 is a cross-sectional view of a superconducting multi-core billet in the first embodiment of the present invention.

FIG. 2 is a cross-sectional view of a superconducting multi-core billet in the second embodiment of the present invention.

FIG. 3A is a cross-sectional view of a superconducting multi-core billet in the third embodiment of the present invention. FIG. 3B is a cross-sectional view of a superconducting multi-core wire in the third embodiment of the present invention.

FIG. 4A is a cross-sectional view of a superconducting multi-core billet in the first comparison example. FIG. 4B is a cross-sectional view of a superconducting multi-core wire in the first comparison example.

FIG. 5 is a cross-sectional view of a superconducting multi-core billet in the second comparison example.

FIG. 6 is a cross-sectional view of a superconducting multi-core billet in the third comparison example.

FIG. 7 is a cross-sectional view of a superconducting magnet that was evaluated for the uniformity of the winding and the quenching of superconductivity.

### DETAILED DESCRIPTION OF THE PREFERRED EMBODIMENTS

The following provides an explanation about embodiments of the present invention referring to drawings.

### Embodiment 1

In the embodiment of the present invention, the superconducting multi-core billet is formed by making plural vertical holes in a copper or copper alloy billet of circular cross-section, wherein the vertical holes are filled with superconducting material comprised of Nb. The volume ratio of copper or copper alloy to superconducting material used in the billet is referred to as the copper ratio.

Usually, a customer places requirements for the range of copper ratio (namely volume ratio of Cu to NbTi), the diameter of superconducting wire, the diameter of superconducting filament, and other particulars. In most cases under this situation, the manufacturer determines the detailed physical construction of a superconducting wire pursuant to the customer's requirement so placed. Where three parameters: the wire diameter d, the superconducting filament diameter d_{sc}, the copper ratio m are specified, the division number N is uniquely determined. Among these, the relationship shown below is valid.

N×π/4×d_{sc}²=1/(m+1)×π/4×d²

Therefore, the division number N is expressed by the equation shown below.

N=1/(m+1)×(d/d_{sc})²

This means that the smaller the copper ratio m becomes, the larger the division number N, namely the number of the vertical holes, increases; or the larger the copper ratio m becomes, the smaller the number of holes reduces.

Superconducting wires become to have high performance as the filament diameter d_{sc} becomes small or as the number of divisions increases, usually with a corresponding increase in the manufacturing cost. In superconducting wires, the superconducting filaments located outer area in terms of the cross-section shows a good workability. Therefore, it is preferable to locate filaments in the outer area as much as possible. This means that filaments should be arrayed in the area in a practicable outermost region within the extent that the requirement for the copper ratio and the filament diameter by the customer permits.

Regarding the cross-sectional construction, a geometrically symmetrical construction is preferred because the symmetry makes the plastic deformation in the cross-section occur uniformly while undergoing the diameter-reduction process. To realize the symmetrical construction, the relationship between the number of vertical holes on the inner layer N₂ and the number of vertical holes on the outer layer N₁ must satisfy N₂=N₁/2 or =N₁/4 or =N₁/8.

This embodiment is applied to such a case that the copper ratio is greater than four. If the copper ratio is three, the number of the filaments and accordingly the number of vertical holes will increase and, as a consequence of this, filaments must be arrayed in three- or four-layer layout, not in two-layer layout as employed in this embodiment. This means that the filaments are forced to be arrayed spreading into even more inner layer area. Further, a wire with small number of division makes as a result the filament diameter d_{sc} be large inviting performance problem.

The reason for the total number of vertical holes N being 20 to 57 is that the superconducting material cannot be divided without causing poor performance if N is smaller than 20 and in contrast that greater N demands much processing cost in making vertical holes, which is not acceptable.

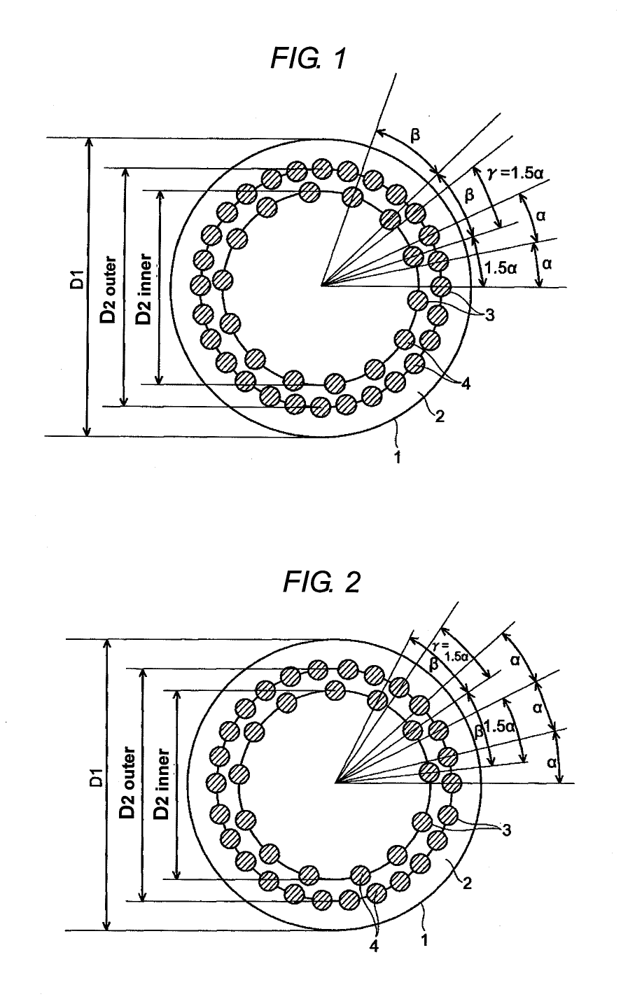

In FIG. 1, the numeral sign 1 denotes a superconducting multi-core billet, 2 denotes a copper or copper alloy billet, 3 vertical holes made in the billet 1, and 4 superconducting material inserted in the vertical holes 3.

In the example that FIG. 1 illustrates, the vertical holes 3 are arrayed on an outer layer concentric circle (D₂ₒᵤₜₑᵣ) and on an inner layer concentric circle (D₂ᵢₙₙₑᵣ), wherein the number of vertical holes arrayed on the outer layer N₁ is 28 and on the inner layer N₂ is 14. The vertical holes 3 are bored at an equal spacing, namely, equiangular spacing of α and β. In other words, the angle α is equal to 360/N₁, namely 12.86°, and the angle β is equal to 360/N₂, namely 25.71°. FIG. 1 illustrates an example of construction where N₁ is 28. In the case where the construction is a two-layer layout, it is preferable that N₁ is an even number of 18 to 38 and N₂ is an integer of 9 to 18.

It is also preferable that the array-angle of the vertical holes 3 on the inner layer is an intermediate value of the array-angle on the outer layer, namely, the angle γ indicated in the figure is 1.5×α. The reason for determining the array-angle of the vertical holes on the inner layer to be an intermediate value of the array-angle on the outer layer is to suppress abnormal deformation of the superconducting filaments. Therefore, it is geometric logic that N₁ is equal to (2 or 4 or 8)×N₂. Accordingly, N₁ must be an even number.

Where the outer diameter of the billet 2 is denoted by D₁, the diameter of the concentric circle D₂ₒᵤₜₑᵣ is approximately D₁×0.8, and similarly D₂ᵢₙₙₑᵣ is approximately D₁×0.6. However, the relationship among D₂ₒᵤₜₑᵣ, D₂ᵢₙₙₑᵣ, and D₁ is not limited only to such range.

Applicable superconducting material 4 for inserting into the vertical holes includes a round NbTi rod, a round copper-covered NbTi rod, or a round NbTi rod having niobium (Nb) sheet or tantalum (Ta) sheet wound thereon. The superconducting multi-core material is manufactured through the processes of fabricating the superconducting multi-core billet 1 as illustrated in FIG. 1, vacuum-sealing both ends thereof with metallic lids, applying hot-extrusion, and drawing and heat-treating under a predetermined condition.

Next, the following provides a detailed explanation about the method for manufacturing a superconducting multi-core wire using the superconducting multi-core billet illustrated in FIG. 1. First, a round copper rod of 235 mm in outer diameter and 850 mm in length is provided as the billet 2. Then, vertical holes 3, the inner diameter of each of which is 15 mm, are made in the billet 2 so that each of the vertical holes 3 will be arrayed on the either of the outer layer concentric circle (having a diameter D₂ₒᵤₜₑᵣ of 184 mm) or the inner layer concentric circle (having a diameter D₂ᵢₙₙₑᵣ of 138 mm). The number of the vertical holes 3 on the outer layer concentric circles N₁ is 28 and on the inner layer concentric circle N₂ is 14; the total number N₁+N₂ is 42. Each of the vertical holes 3 is bored on the concentric circle with even spacing, namely, equi-angles of α (12.86°) and β (25.71°).

The array-angle of the vertical holes 3 on the inner layer is an intermediate value of the array-angle on the outer layer, namely, an angle of 1.5×α as illustrated in the figure.

A superconducting multi-core (42 cores) wire having a finish diameter of wire of 1.2 mm was manufactured through the processes of inserting a round NbTi rod having an outer diameter of 14.8 mm, the superconducting material 4, into the vertical holes 3; vacuum-sealing both ends thereof with metallic lids; and applying hot-extrusion, and drawing and heat-treating repeatedly under a predetermined condition.

The sectional area of the copper (the billet 2) of the superconducting multi-core billet 1 for this superconducting multi-core wire is

3.14×(235/2)²−3.14×(28+14)×(15/2)²=35933 mm²,

and the sectional area of the superconducting material 4 is

3.14×(28+14)×(14.8/2)²=7222 mm².

Therefore, the copper ratio is 35933/7222, namely 5.

No wire breaks occurred during drawing in this embodiment until the process reached the finish diameter of wire. In reality, the frequency of occurrence of wire break during drawing down to the finish diameter of wire in terms of probability is very low. Therefore, an experimental evaluation of a quantitative differentiation needs the processing of a huge length of material. Here, to make a comparative investigation into the frequency of occurrence of wire break, material worked down to the finish diameter of wire was prepared and the material further underwent three times of drawing with an area-reduction rate of 26%. The material so processed was put under evaluation by counting the number of wire breaks occurred during such three-time drawing. This means that the wire underwent three times of die-drawing from the diameter 1.28 mm (finish diameter) down to 1.03 mm to 0.888 mm further to 0.763 and during which the number of wire breaks per wire length was counted.

As a result of the study made diligently by the inventor of the present invention, the inventor gained such a knowledge that the additional three times of drawing makes the frequency of occurrence of wire break increase to the extent about 100 times the frequency that appears during the drawing down to the finish diameter of wire where the frequency of occurrence of wire break in terms of the wire length until the processing reaches the finish diameter of wire is defines as P (break/km). In this description of the present invention, the results of the evaluation of the frequency of occurrence of wire breaks is expressed in a value converted into the frequency of occurrence of wire break that would appear at the stage of the finish diameter of wire by multiplying the measured break occurrence by 100.

In this embodiment, the frequency of occurrence of wire break converted into the length of the finish diameter of wire was 0.0008 break/km, which confirmed that the invented manufacturing method satisfies the requirement (the frequency of occurrence of wire break shall be less than 0.001 break/km).

### Embodiment 2

In the second embodiment, the number of vertical holes on the inner layer N₂ of the billet was determined to be a prime number. This embodiment employed a geometrically asymmetrical construction based on a prime number purposely applied to the determination of the number of the vertical holes on the inner layer but the embodiment still used a symmetrical construction in terms of plastic deformation. The reason for N₂ being a prime number is that an abnormal deformation of the superconducting filaments during drawing process is suppressed.

As well as the embodiment 1, the embodiment 2 is applied to such a case that the copper ratio is greater than four. The relationship between the number of the vertical holes on the inner layer N₂ and the number of vertical holes on the outer layer N₁ was determined by the equation N₂=N₁/2 or N₁/2 or N₁/8, as in the embodiment 1.

In the example that FIG. 2 illustrates, the vertical holes 3 are arrayed on an outer layer concentric circle (D₂ₒᵤₜₑᵣ) and on an inner layer concentric circle (D₂ᵢₙₙₑᵣ), wherein the number of vertical holes arrayed on the outer layer N₁ is 26 and on the inner layer N₂ is 13. The vertical holes 3 are bored at an equal spacing, namely, equiangular spacings of α and β, as in the embodiment 1. In other words, the angle α is 360/N₁, namely 13.85°, and the angle β is 360/N₂, namely 27.69°. Though the construction illustrated in FIG. 2 is different from the one illustrated in FIG. 1, it is preferable that N₂ is a prime number of 3 to 19 and N₁ is an even number that satisfies N₁>2×N₂. As well as the embodiment 1, it is also preferable that the array-angle of the vertical holes 3 on the inner layer is an intermediate value of the array-angle on the outer layer, namely, the angle of 1.5×α as indicated in the figure. The relationship between D₂ₒᵤₜₑᵣ and D₂ᵢₙₙₑᵣ is the same as in the embodiment 1.

As well as the embodiment 1, applicable superconducting material 4 for inserting into the vertical holes 3 is a round NbTi rod. The superconducting multi-core wire was manufactured through the processes of fabricating the superconducting multi-core billet 1 as illustrated in FIG. 2, vacuum-sealing both ends thereof with metallic lids, applying hot-extrusion, and drawing and heat-treating under a predetermined condition.

Next, the following provides a detailed explanation about the method for manufacturing the superconducting multi-core billet illustrated in FIG. 2. First, a round copper rod of 235 mm in outer diameter and 850 mm in length is provided as the billet 2. Then, vertical holes 3, the inner diameter of each of which is 15 mm, are made in the billet 2 so that each of the vertical holes 3 will be arrayed on the either of the outer layer concentric circle (having a diameter D₂ₒᵤₜₑᵣ of 184 mm) or the inner layer concentric circle (having a diameter D₂ᵢₙₙₑᵣ of 140 mm). The number of the vertical holes 3 on the outer layer concentric circle N₁ is 26 and on the inner layer concentric circle N₂ is 13; the total number N₁+N₂ is 39. Each of the vertical holes 3 are bored on the concentric circle at even spacing, namely, an equi-angles of α (13.85°) and β (27.69°).

The array-angle of the vertical holes 3 on the inner layer is an intermediate value of the array-angle on the outer layer, namely, the angle 1.5×α as illustrated in the figure. A superconducting multi-core (39 cores) wire 1 having a finish diameter of wire of 1.2 mm was manufactured through the processes of inserting a round NbTi rod having an outer diameter of 14.8 mm, the superconducting material 4, into the vertical holes 3; vacuum-sealing both ends thereof with metallic lids; and applying hot-extrusion, and drawing and heat-treating repeatedly under a predetermined condition.

The sectional area of the copper (the billet 2) of the superconducting multi-core billet 1 for this superconducting multi-core wire is

3.14×(235/2)²−3.14×(26+13)×(15/2)²=35933 mm²,

and the sectional area of the superconducting material 4 is

3.14×(26+13)×(14.8/2)²=6706 mm².

Therefore, the copper ratio is 36463/6706, namely 5.4.

No wire breaks occurred during drawing until the process reached the finish diameter of wire.

The frequency of occurrence of wire break converted, in the same manner as in the embodiment 1, into the length of the finish diameter of wire was 0.0004 break/km, which confirmed that the invented manufacturing method satisfies the requirement (the frequency of occurrence of wire break shall be less than 0.001 break/km).

Table 1 is a list of the number of vertical holes in those constructions in the embodiments of the present invention as illustrated in FIGS. 1 and 2. The rightmost column of the Table 1 indicates the evaluation results of the wire break being denoted by signs ⊚, ◯, and x. Each sign means
x: Wire breaks occurred more than 0.001 breaks per 1 km of length,
◯: Wire breaks occurred less than 0.001 breaks per 1 km of length,
⊚: Wire breaks occurred less than 0.0005 breaks per 1 km of length.

TABLE 1

| Cross- | | | Total | |
|---|---|---|---|---|
| sectional | | Number of | Number of | Evaluation of |
| Construction | Number of | Vertical | Vertical | Frequency of |
| Identification | Vertical Holes | Holes | Holes | Occurrence of |
| No. | N₁ | N₂ | N = N₁ + N₂ | Wire Break |
| 1 | 16 | 8 | 24 | ◯ |
| 2 | 16 | 4 | 20 | ◯ |
| 3 | 18 | 9 | 27 | ◯ |
| 4 | 20 | 10 | 30 | ◯ |
| 5 | 20 | 5 | 25 | ◯ |
| 6 | 22 | 11 | 33 | ⊚ |
| 7 | 24 | 12 | 36 | ◯ |
| 8 | 24 | 6 | 30 | ◯ |
| 9 (FIG. 2) | 26 | 13 | 39 | ⊚ |
| 10 (FIG. 1) | 28 | 14 | 42 | ◯ |
| 11 | 28 | 7 | 35 | ⊚ |
| 12 | 30 | 15 | 45 | ◯ |
| 13 | 32 | 16 | 49 | ◯ |
| 14 | 32 | 8 | 40 | ◯ |
| 15 | 32 | 4 | 36 | ◯ |
| 16 | 34 | 17 | 51 | ⊚ |
| 17 | 36 | 18 | 54 | ◯ |
| 18 | 36 | 9 | 45 | ◯ |
| 19 | 38 | 19 | 57 | ⊚ |

### Embodiment 3

In the third embodiment, the vertical holes are made in the billet so that each of the vertical holes will be arrayed on one layer of concentric circle that is concentric with respect to the center of the billet and the number of the holes N is 29. As well as the embodiments 2 and 3, the vertical holes are bored at an equal spacing, namely, an equi-angle of α. In this embodiment, wherein the number N is 29, the equi-angle β is 360/N, namely 12.4°.

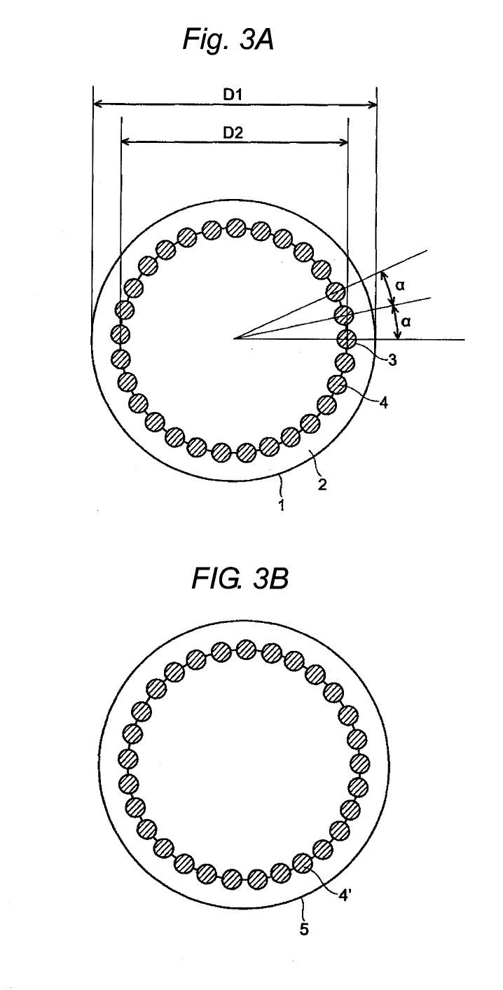

In FIGS. 3A and 3B, the numeral sign 1 denotes a superconducting multi-core billet, 2 denotes a copper or copper alloy billet, 3 vertical holes made in the billet 1, 4 superconducting material inserted in the vertical holes 3, and 5 a superconducting multi-core wire obtained from the superconducting multi-core billet 1 by working applied thereon.

FIG. 3A illustrates the construction in the case where N is 29, wherein N should preferably be an integer of 17 to 53. Further, it is preferable that N is a prime number such as 17, 19, 23, 29, 31, 37, 41, 43, 47, 51, and 53, or instead that N is the product of a prime number Nₐ of three or greater and a prime number N_{b} of five or greater, namely one of 33, 35, and 39. The reason for determination of N being a prime number or the product of prime numbers is that there is an expectation for suppression of abnormal deformation of the superconducting filaments while drawing operation, improving the uniformity of the magnetic field generated by the superconducting magnet, and repressing the quenching of superconductive magnet. Employing such a construction that the number of vertical holes for superconducting wire material is a prime number or the product of a prime number Nₐ of three or greater and a prime number N_{b} of five or greater brings an expectation for suppression of unevenness due to positional deviation of winding that may occur during coil-winding process or due to something particular to the equipment, for eventual obtainment of a superconducting coil with excellent uniformity, and for the effect of suppressing the quenching of superconductivity.

As well as the embodiments 1 and 2, the embodiment 3 is applied to such a case that the copper ratio is greater than four. Where the outer diameter of the billet 2 is denoted by D₁ and the diameter of the concentric circle is denoted by D₂, it is preferable that D₂/D₁ is 0.7 to 0.85.

As well as the embodiments 1 and 2, applicable superconducting material 4 for inserting into the vertical holes 3 is a round NbTi rod. The superconducting multi-core wire is manufactured through the processes of fabricating the superconducting multi-core billet, vacuum-sealing both ends thereof with metallic lids, applying hot-extrusion, and drawing and heat-treating under a predetermined condition.

Next, the following provides a detailed explanation about the method for manufacturing the superconducting multi-core wire 5 illustrated in FIG. 3B. First, a round copper rod of 235 mm in outer diameter and 850 mm in length is provided as the billet 2. Then, vertical holes 3, the inner diameter of each of which is 15 mm, are made in the billet 2 so that each of the vertical holes 3 will be arrayed on the either of the outer layer concentric circle (having a diameter D₂ₒᵤₜₑᵣ of 184 mm) or the inner layer concentric circle (having a diameter D₂ᵢₙₙₑᵣ of 140 mm). The number of the vertical holes 3 on the outer layer concentric circle N is 29 and the vertical holes are bored at even spacing, namely, an angle of α (12.4°).

A superconducting multi-core (29 cores) wire 5 having a finish diameter of wire of 1.2 mm was manufactured through the processes of inserting a round NbTi rod having an outer diameter of 14.8 mm, the superconducting material 4, into the vertical holes 3; vacuum-sealing both ends thereof with metallic lids; and applying hot-extrusion, and drawing and heat-treating repeatedly under a predetermined condition.

The sectional area of the copper (the billet 2) of the superconducting multi-core billet 1 for this superconducting multi-core wire 5 is

3.14×(235/2)²−3.14×29×(15/2)²=38230 mm²,

and the sectional area of the superconducting material 4 is

3.14×29×(14.8/2)²=4986 mm².

Therefore, the copper ratio is 38230/4986, which is 7.7.

No wire breaks occurred during drawing until the process reached the finish diameter of wire. The shape of the superconducting part 4′ maintained its circularity. It is thought that, because of this, the frequency of occurrence of wire break was reduced.

The frequency of occurrence of wire break converted, in the same manner as in the embodiment 1, into the length of the finish diameter of wire was 0.0002 break/km, which confirmed that the invented manufacturing method satisfies the requirement (the frequency of occurrence of wire break shall be less than 0.001 break/km).

### Embodiment 4

The embodiment 4 is similar to the embodiment 3 in terms of construction and manufacturing method, wherein the number of the superconducting material arrayed on the outer layer concentric circle N is 28. As well as the embodiments 1 to 3, applicable superconducting material for inserting into the vertical holes is a round NbTi rod. The superconducting multi-core wire is manufactured through the processes of fabricating the superconducting multi-core billet, vacuum-sealing both ends thereof with metallic lids, applying hot-extrusion, and drawing and heat-treating under a predetermined condition.

The following provides an explanation without referring to drawings, wherein aspects are similar to the embodiment 3. First, a round copper rod of 235 mm in outer diameter and 850 mm in length is provided as the billet. Then, vertical holes, inner diameter of each of which is 15 mm, are made in the billet so that each of the vertical holes will be arrayed on the outer layer concentric circle (having a diameter D₂ₒᵤₜₑᵣ of 184 mm). The number of the vertical holes on the outer layer concentric circle N is 28 and the vertical holes are bored at even spacing, namely, an angle of α (that is 12.8°=360/28).

A superconducting 28-core wire having a finish diameter of wire of 1.2 mm was manufactured through the processes of inserting a round NbTi rod having an outer diameter of 14.8 mm, the superconducting material, into the vertical holes; vacuum-sealing both ends thereof with metallic lids; and applying hot-extrusion, and drawing and heat-treating repeatedly under a predetermined condition. To make the copper ratio in this embodiment be the same as the one in the embodiment 3, the outer part of the copper layer was removed in the middle of drawing processing so that the copper ratio will become 7.7. No wire breaks occurred during drawing until the process reached the finish diameter of wire.

The frequency of occurrence of wire break converted, in the same manner as in the embodiment 1, into the length of finish diameter of wire was 0.0008 break/km. In this embodiment, the frequency of occurrence of wire break was larger than that in the embodiment 3. It is thought that the reason for this is that the number of the vertical holes N was not a prime number but 28. However, this construction was judged practicable because the results satisfied the requirement (the frequency of occurrence of wire break shall be less than 0.001 break/km).

An observation of cross-section of filaments in the superconducting multi-core billet of the above-stated embodiments under an optical microscope after diameter-reduction process such as extrusion and drawing confirmed that they maintained their construction at an almost true-circle.

In the case that the construction as described in the embodiment 4 is used, the circularity of the superconducting elements is maintained at an almost unchanged level during and even after the diameter-reduction process that applies complicated forces as stated above. Thus, it is evident that a quantum leap in the reduction of the frequency of occurrence of wire break is realized.

### Embodiment 5

The embodiment 5 is a modification of the embodiment 3, wherein the vertical holes are made in the billet so that each of the vertical holes will be arrayed on one concentric circle that is concentric with respect to the outer diameter of the billet and the number of the vertical holes N is 33, 35, and 39. The vertical holes are bored at an equal spacing, namely an equi-angle of α. In this embodiment, where N is 33 then α is 360/33, namely 10.9°; N is 35, α is 360/35=10.3°; and N is 39, α is 360/39=9.2°.

N is preferred to be the product of a prime number Nₐ of three or greater and a prime number N_{b} of five or greater, namely one of 33, 35, and 39. The reason for determination of N being a prime number or the product of prime numbers is that there is an expectation for suppression of abnormal deformation of the superconducting filaments while drawing operation, improving the uniformity of the magnetic field generated by the superconducting magnet, and repressing the quenching of superconductive magnet. Employing such a construction in manufacturing the superconducting multi-core wire that the number of vertical holes for superconducting wire material is a prime number or the product of a prime number Nₐ of three or greater and a prime number N_{b} of five or greater brings an expectation for suppression of unevenness due to positional deviation of coil that may occur during winding process or due to something particular to the equipment, for eventual obtainment of a superconducting coil with excellent uniformity, and for the effect of suppressing the quenching in superconductivity.

As well as the embodiment 3, this embodiment is applied to such a case that the copper ratio is greater than four. Where the outer diameter of the billet is denoted by D₁ and the diameter of the concentric circle is denoted by D₂, it is preferable that D₂/D₁ is 0.7 to 0.85.

As well as the embodiment 3, applicable superconducting material for inserting into the vertical holes is a round NbTi rod. The superconducting multi-core wire is manufactured through the processes of fabricating the superconducting multi-core billet, vacuum-sealing both ends thereof with metallic lids, applying hot-extrusion, and drawing and heat-treating under a predetermined condition.

Next, a detailed explanation is provided about the manufacturing method of the super conducting multi-core wire in which N is 33. First, a round copper rod of 235 mm in outer diameter and 850 mm in length is provided as the billet. Then, vertical holes, inner diameter of each of which is 15 mm, are made in the billet so that each of the vertical holes will be arrayed on the outer layer concentric circle (having diameter D₂ₒᵤₜₑᵣ of 184 mm). The number of the vertical holes on the outer layer concentric circle N is 33 and the vertical holes are bored at even spacing, namely, an angle of α (10.9°).

A superconducting 33-core wire having a finish diameter of wire of 1.2 mm was manufactured through the processes of inserting a round NbTi rod having an outer diameter of 14.8 mm into the vertical holes; vacuum-sealing both ends thereof with metallic lids; and applying hot-extrusion, and drawing and heat-treating repeatedly under a predetermined condition.

The sectional area of the copper (the billet) of the superconducting multi-core billet for this superconducting multi-core wire is

3.14×(235/2)²−3.14×33×(15/2)²=37523 mm²,

and the sectional area of the superconducting material is

3.14×33×(14.8/2)²=5677 mm².

Therefore, the copper ratio is 37523/5677, namely 6.6.

No wire breaks occurred during drawing until the process reached the finish diameter of wire. The cross-sectional construction of the wire after the diameter-reduction process is the same as illustrated in FIG. 3B. The shape of the super conducting elements maintained their true-circle construction and therefore it is thought that, because of this, the frequency of occurrence of wire break was reduced.

The frequency of occurrence of wire break converted, in the same manner as in the embodiment 1, into the length of the finish diameter of wire was 0.0002 break/km, which confirmed that the invented manufacturing method satisfies the requirement (the frequency of occurrence of wire break shall be less than 0.001 break/km).

### Comparison Example 1

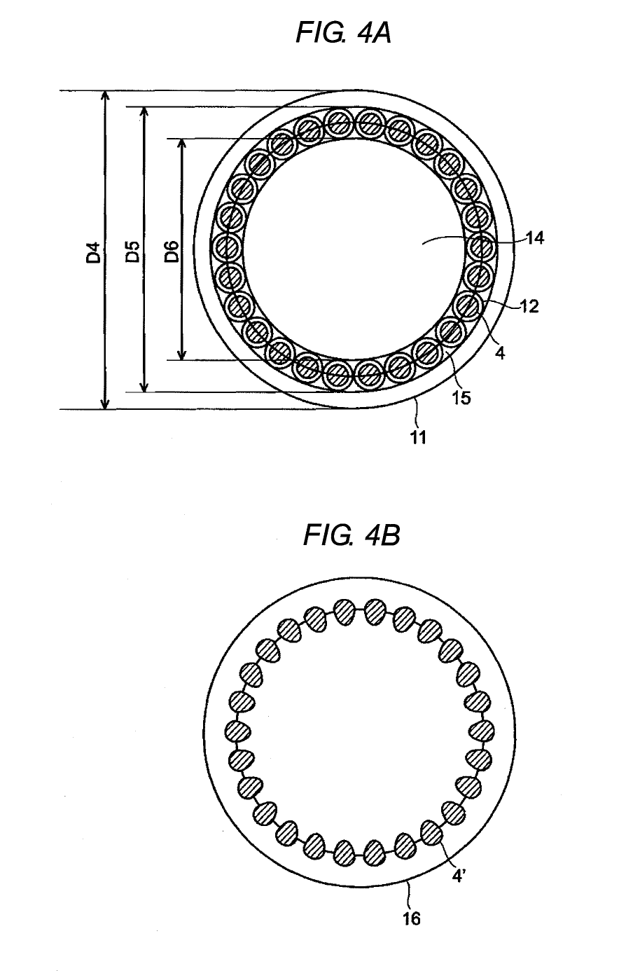

The construction of a billet as the comparison example 1 is illustrated in FIG. 4A. A superconducting composite billet was fabricated through the processings of preparing a single-core wire 12 (a copper covered superconducting material 4) made of Cu/NbTi having a copper ratio of 0.4; drawing the single-core wire 12 down to a wire of 16 mm in diameter; and inserting 26 wires of the single-core wire 12 so drawn and one round central copper rod 14 of 181 mm in diameter into a copper tube 11 (234 mm in outer diameter and 214 mm in inner diameter). Dimensions indicated by each of the signs appeared in the figure are D₄=234 mm, D₅=214 mm, and D₆=181 mm. By applying hot extrusion, drawing, and heat treatment to the superconducting composite billet, a 26-core superconducting wire 16 as illustrated in FIG. 4B having a diameter of 1.2 mm was manufactured. No wire breaks occurred during drawing in this embodiment until the process reached the finish diameter of wire.

However, the frequency of occurrence of wire break converted, in the same manner as in the embodiment 1, into the length of the finish diameter of wire was 0.002 break/km, which meant that the manufacturing method was not such a method as satisfies the requirement (the frequency of occurrence of wire breaks shall be less than 0.001 break/km). It is thought that the reason for increased frequency of occurrence of wire break is that the fabrication of the superconducting composite billet formed air gaps 15 in its cross-sectional construction. The air gap 15 prevents the single-core wire 4 from a uniform deformation with geometrical similarity maintained during extrusion of and diameter reduction processes by drawing of the superconducting composite bullet and, as a consequence, causes irregular diameter reduction deformation. Thus, it is thought that the filament (the single-core wire 4′ after diameter reduction process) becoming noncircular led to the frequent occurrence of wire breaks.

FIG. 4B illustrates the cross-sectional aspect after drawing processing. In the comparison example 1, the diameter reduction processing makes the filament 4′ noncircular.

### Comparison Example 2

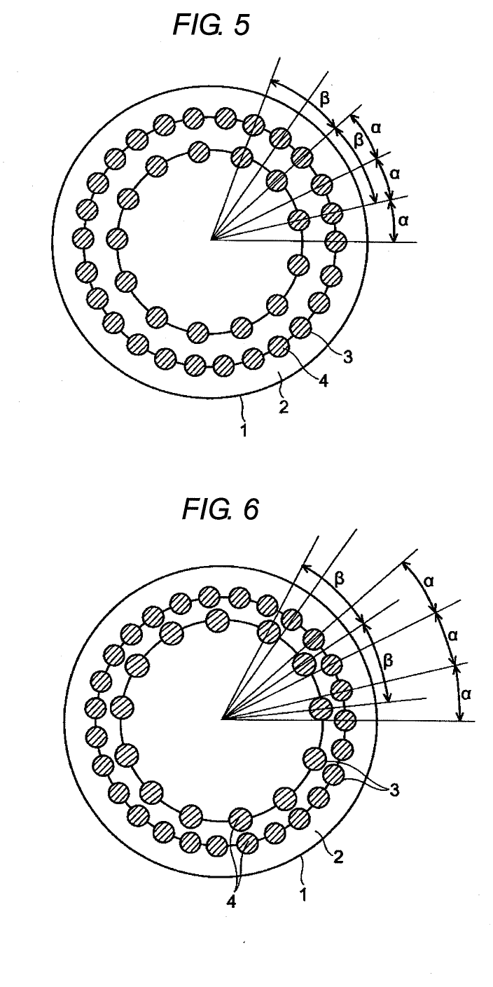

The following explains the comparison example 2 referring to FIG. 5. The difference from the embodiment 2 is the arraying layout of the vertical holes 3 on the inner layer. In the embodiment 2, the array-angle of the vertical holes 3 is an intermediate value of the array-angle on the outer layer, namely, the angle of 1.5×α as indicated in the figure. In this comparison example in contrast, the vertical holes 3 are arrayed on the same angular position. Similarly to the embodiment 2, a superconducting multi-core (39 cores) wire having a finish diameter of wire of 1.2 mm was manufactured through the processes of inserting a round NbTi rod having an outer diameter of 14.8 mm; vacuum-sealing both ends thereof with metallic lids; and applying hot-extrusion, and drawing and heat-treating repeatedly under a predetermined condition.

The sectional area of the copper (the billet 2) of this superconducting multi-core billet 1 for this superconducting multi-core wire is

3.14×(235/2)²−3.14×(26+13)×(15/2)²=36463 mm²,

and the sectional area of the superconducting material 4 is

3.14×(26+13)×(14.8/2)²=6706 mm².

Therefore, the copper ratio is 36463/6706, namely 5.4. These values are the same as those in the embodiment 2.

No wire breaks occurred during drawing until the process reached the finish diameter of wire.

The frequency of occurrence of wire break converted, in the same manner as in the embodiment 1, into the length of the finish diameter of wire was 0.001 break/km, which meant that the method was not such a method as satisfies the requirement (the frequency of occurrence of wire break shall be less than 0.001 break/km).

### Comparison Example 3

The following explains the comparison example 3 referring to FIG. 6. This example is the case where the number of vertical holes arrayed on the inner layer N₂ is 13, wherein however the number of holes arrayed on the outer layer N₁ is 27, which is a different number from the embodiment 2. It is not an even-multiple number but N₁ is 27. Accordingly, α is 360/N₁, namely 13.3°. In this construction, it is geometrically impossible to make all the array-angles of the vertical holes on the inner layer be the intermediate value of the array angle on the outer layer. If one of the vertical holes on the inner layer is defined as the center of the angle α, the angle of intermediate value γ cannot be 1.5α as illustrated in FIG. 6.

In this example, the drawing evaluation applied thereto in a similar manner to other cases revealed that the frequency of occurrence of wire break was 0.004 break/km, which meant that the manufacturing method was not such a method as satisfies the requirement (the frequency of occurrence of wire break shall be less than 0.001 break/km).

### Comparison Example 4

The following explains the comparison example 4. This comparison example is the case where the number of vertical holed arrayed on the inner layer N₂ is 13, wherein however the number of holes arrayed on the outer layer N₁ is 25, which is different a number from the embodiment 2. It is not an even-multiple number but N₁ is 25. Accordingly, α is 360/N₁, namely 14.4°. In this construction, it is geometrically impossible to make all the array-angles of the vertical holes on the inner layer be the intermediate value of the array angle on the outer layer.

In this example, the drawing evaluation applied thereto in a similar manner to other cases revealed that the frequency of occurrence of wire break was 0.004 break/km, which meant that the manufacturing method was not such a method as satisfies the requirement (the frequency of occurrence of wire break shall be less than 0.001 break/km).

Table 2 is a list of the number of vertical holes and the frequencies of occurrence of wire break in those constructions in the comparison examples 1 to 4 (FIGS. 4 to 6). The rightmost column of the Table 2 indicates, similarly to Table 1, the evaluation results of the wire break being denoted by signs ⊚, ◯, and x.

### Comparison Examples 5 to 9

In the comparison examples 5 to 9, the vertical holes are made in the billet so that each of the vertical holes will be arrayed on one concentric circle that is concentric with respect to the outer diameter of the billet and the numbers of the vertical holes N are 30, 32, 34, 36, and 38. Similarly to the embodiments 2 and 3, the vertical holes are bored at an equal spacing, namely an equi-angle of α. In the comparison example, when N is 30, then α is 360/N, namely 12°.

As well as the embodiment 3, applicable superconducting material for inserting into the vertical holes is a round NbTi rod. The superconducting multi-core wire was manufactured through the processes of fabricating the superconducting multi-core billet, vacuum-sealing both ends thereof with metallic lids, applying hot-extrusion, and drawing and heat-treating under a predetermined condition.

In these examples, first, a round copper rod of 235 mm in outer diameter and 850 mm in length was provided. Then, vertical holes, inner diameter of each of which is 15 mm, were made in the round copper rod so that each of the vertical holes would be arrayed on the outer layer concentric circle (having diameter D₂ of 184 mm). The number of the vertical holes on the outer layer concentric circle N was 30 (the comparison example 5), 32 (the comparison example 6), 34 (the comparison example 7), 36 (the comparison example 8), and 38 (comparison example 9). Each of the vertical holes was bored at even spacing.

And then, a superconducting multi-core wire (30-, 32-, 34-, and 36-core) having a finish diameter of wire of 1.2 mm was manufactured through the processes of inserting a round NbTi rod having an outer diameter of 14.8 mm into the vertical holes; vacuum-sealing both ends thereof with metallic lids; and applying hot-extrusion, and drawing and heat-treating repeatedly under a predetermined condition.

The frequencies of occurrence of wire break converted, in the same manner as in the embodiment 1, into the length of the finish diameter of wire were:
0.001 break/km in the comparison example 5 (30-core),
0.008 break/km in the comparison example 6 (32-core),
0.004 break/km in the comparison example 7 (34-core),
0.002 break/km in the comparison example 8 (36-core), and
0.001 break/km in the comparison example 9 (38-core).

Thus, none of these methods was such a method as satisfies the requirement (the frequency of occurrence of wire break shall be less than 0.001 break/km).

TABLE 2

| | | | | | Evaluation |
|---|---|---|---|---|---|
| | | | | Total | of |
| | Cross- | Number | Number | Number of | Frequency |
| | sectional | of | of | Vertical | of |
| | Construction | Vertical | Vertical | Holes | Occurrence |
| | Illustration | Holes | Holes | N = | of Wire |
| Example | No. | N₁ | N₂ | N₁ + N₂ | Break |
| Comparison | FIG. 4 | Number of filaments = 26 | | | x |
| Example 1 | | Manufactured by same | | | |
| | | method as conventional one | | | |
| Comparison | FIG. 5 | 13 | 26 | 39 | x |
| Example 2 | | | | | |
| Comparison | FIG. 6 | 13 | 27 | 40 | x |
| Example 3 | | | | | |
| Comparison | Not | 13 | 25 | 38 | x |
| Example 4 | illustrated | | | | |
| Comparison | Not | 30 | No | 30 | x |
| Example 5 | illustrated | | holes | | |
| Comparison | Not | 32 | No | 32 | x |
| Example 6 | illustrated | | holes | | |
| comparison | Not | 34 | No | 34 | x |
| Example 7 | illustrated | | holes | | |
| Comparison | Not | 36 | No | 36 | x |
| Example 8 | illustrated | | holes | | |
| Comparison | Not | 38 | No | 38 | x |
| Example 9 | illustrated | | holes | | |

As stated above, the present invention can reduce the manufacturing time (cost) and the frequency of occurrence of wire break during diameter-reduction drawing of superconducting multi-core wires, because the invention as described in the embodiments 1 to 4 optimizes the number of the vertical holes in the superconducting multi-core billet. Further, specifying the number of the vertical holes in the billet to be a prime number disperses the tension eliminating local concentration; thereby the wire break during diameter-reduction drawing is suppressed.

### Other Embodiments

Coils were formed simulating a use for the nuclear magnetic resonance technique (NMR-use) using windings of superconducting multi-core wires by the present invention and superconducting multi-core wires defined in the comparison examples. The coils so formed were fabricated into superconducting magnets, which were put under a comparative investigation into the degree of uniformity of their magnetic fields and the quenching behaviors. An enamel insulation treatment was applied over a superconducting multi-core wire having a diameter of 1.2 mm to provide a superconducting magnet wire having a diameter of 1.3 mm. Using eight types of wires as the windings, 13 NMR-simulated superconducting magnets were manufactured as listed in Table 3.

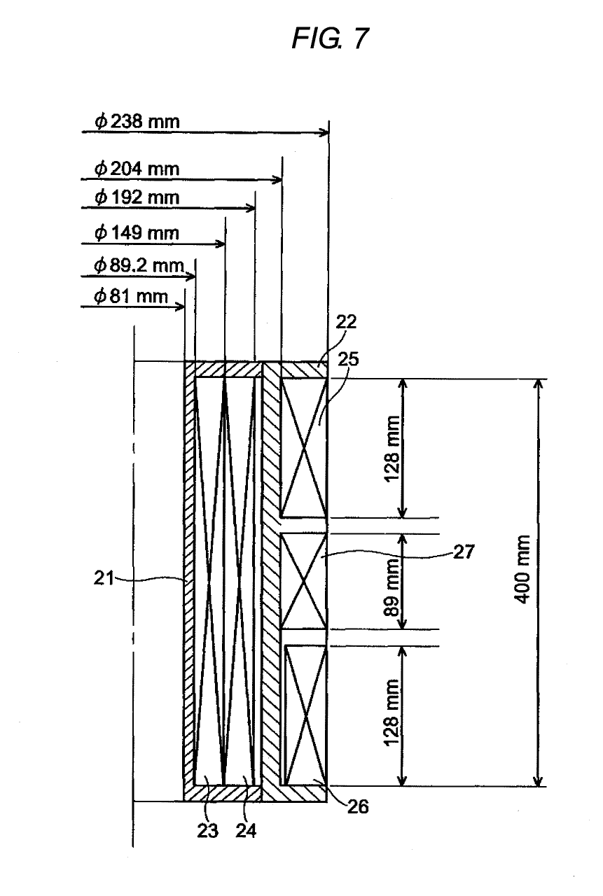

FIG. 7 illustrates the construction (a half-portion from the center of symmetrical configuration) of the NMR-simulated superconducting coil provided for evaluation purpose. This NMR-simulated coil provides two layers of inner and outer copper winding bobbins 21 and 22. On the inner copper winding bobbin 21, a main coil 23 was wound; and an outer coil 24 was wound over the main coil 23. On the outer copper winding bobbin 22, three coils were arrayed in an axial arrangement (namely, an upper sub-coil 25, a middle sub-coil 27, and a lower sub-coil 26).

Each of the NMR-simulated superconducting magnets has an NMR-simulated superconductive coil comprised of five coils dimensioned as listed in Table 4: the main coil, the outer coil, two upper and lower sub-coils, and middle sub-coil. Table 4 lists an example of the shape (dimensions) of the NMR-simulated superconducting magnet.

The coil for the superconducting magnet is manufactured in the following manner. The superconducting wire specified in the Table 3 severally as Embodiments A to E is wound on the copper bobbin traversing from the top end down to the bottom end thereof and then similarly from the bottom end to the top end. This winding procedure is repeated several times to complete. In this evaluation, above-stated coils were all manufactured using one kind of or a combination of two kinds of superconducting wires as listed in Table 3. However, other combination of superconducting wires different from those listed combinations may be practicable. Further, using only one kind of wire selected from among the invented superconducting wires may be feasible. More sophisticated construction may be used in the copper bobbin.

The evaluation of the degree of uniformity of the magnetic field was made by measuring the 1/10 crest value by the spectrum analysis using an NMR signal probe with the magnet exited to a specified field strength. The 1/10 crest value is an index that shows the magnetic field is spatially uniform, wherein the smaller is the crest value, the more uniform is the magnetic field. For practical purposes, there is no problem when the degree of uniformity is not greater than 0.5 ppm.

The quenching current of the superconducting magnet was evaluated measuring the load factor with respect to the critical current density of the wire applying the current to the magnet coil for excitation, with the superconducting coil immersed in liquid helium actually. The quenching test was conducted two times. Repeating the test two or three times usually causes the load factor to approach 100%. It is ideal that the load factor increases within a smaller number of trainings. The superconducting magnet is applicable for practical purposes where the load factor is 95% or more.

As listed in Table 3, it can be known that use of wires defined in the embodiments provides an advantageous superconducting magnet in terms of the degree of uniformity of magnetic field and the quenching in superconductivity.

It is thought that this advantage is because of that the introduction of a prime number or the product between prime numbers in the filament array suppresses the irregularity in winding or the quenching in superconductivity.

The most preferable case is the Embodiment C, wherein the number of the superconducting filaments is the prime number. On the other hand, the Embodiment E, wherein the number is the product of a prime number Na and a prime number Nb, also shows an advantageous effect. In contrast in the comparison examples, the degree of uniformity of magnetic field and the load factor quench characteristics are not acceptable. Although the array in the comparison example B satisfies the condition that the number is the product of a prime number Na and a prime number Nb and accordingly the quench characteristics is good, the degree of uniformity of magnetic field and aspects in manufacturing the wire are disadvantageous.

The styles of the superconducting magnet in application are various, which include other various medical purpose diagnostic equipment such as magnetic resonance imaging (MRI), magnets for physical property evaluation, and accelerators. The present invention is not limited to the construction of magnets. The present invention is applicable to all the cases where the wire having the invented construction is to be used for coil windings.

TABLE 3
Superconducting Magnets

| | | | Finished Shape | | | Load Factor Quench | |
|---|---|---|---|---|---|---|---|
| | | | (Conductor) | Uniformity of | | Characteristics | |
| | Wire Used | | Outer Diameter | Magnetic | | First | Second |
| Examples | Main coil | Other Coil | (mm) | Field | | Excitation | Excitation |
| Embodiment A | Wire used in embodiment 1 | Wire used in embodiment 3 | 1.2 | 0.4 | ppm | 45% | 98% |
| | 42 cores (on 2 layers) | 29 cores (on 1 layer) | | | | | |
| | Copper ratio 5.0 | Copper ratio 7.7 | | | | | |
| Embodiment B | Wire used in embodiment 2 | Wire used in embodiment 3 | 1.2 | 0.4 | ppm | 65% | 98% |
| | 39 cores (on 2 layers) | 29 cores (on 1 layer) | | | | | |
| | Copper ratio 5.4 | Copper ratio 7.7 | | | | | |
| Embodiment C | Wire used in embodiment 3 | Same as on the left | 1.2 | 0.4 | ppm | 85% | 99% |
| | 29 cores (on 1 layer) | | | | | | |
| | Copper ratio 7.5 | | | | | | |
| Embodiment D | Wire used in embodiment 4 | Same as on the left | 1.2 | 1.0 | ppm | 45% | 96% |
| | 28 cores (on 1 layer) | | | | | | |
| | Copper ratio 7.7 | | | | | | |
| Embodiment E | Wire used in embodiment 5 | Wire used in embodiment 3 | 1.2 | 0.5 | ppm | 55% | 97% |
| | 33 cores (on 2 layers) | 29 cores (on 1 layer) | | | | | |
| | copper ratio 6.6 | Copper ratio 7.7 | | | | | |
| Comparison | Wire used in | Wire used in | 1.2 | 2 | ppm | 35% | 45% |
| Example A | comparison example 1 | comparison example 5 | | | | | |
| | 26 cores (on 1 layer) | 30 cores (on 1 layer) | | | | | |
| | Copper ratio 5.3 | Copper ratio 7.5 | | | | | |
| Comparison | Wire used in | Wire used in | 1.2 | 1 | ppm | 77% | 99% |
| Example B | comparison example 2 | comparison example 5 | | | | | |
| | 39 cores (on 2 layers) | 30 cores (on 1 layer) | | | | | |
| | Copper ratio 5.4 | Copper ratio 7.5 | | | | | |
| Comparison | Wire used in | Wire used in | 1.2 | 4 | ppm | 65% | 77% |
| Example C | comparison example 3 | comparison example 5 | | | | | |
| | 41 cores (on 1 layer) | 30 cores (on 1 layer) | | | | | |
| | Copper ratio 5.3 | Copper ratio 7.5 | | | | | |
| Comparison | Wire used in | Wire used in | 1.2 | 4 | ppm | 65% | 77% |
| Example D | comparison example 4 | comparison example 5 | | | | | |
| | 38 cores (on 1 layer) | 30 cores (on 1 layer) | | | | | |
| | Copper ratio 5.5 | Copper ratio 7.5 | | | | | |
| Comparison | Wire used in | Wire used in | 1.2 | 6 | ppm | 65% | 77% |
| Example E | comparison example 5 | comparison example 5 | | | | | |
| | 30 cores (on 1 layer) | 30 cores (on 1 layer) | | | | | |
| | Copper ratio 7.5 | Copper ratio 7.5 | | | | | |
| Comparison | Wire used in | Wire used in | 1.2 | 12 | ppm | 35% | 57% |
| Example F | comparison example 6 | comparison example 5 | | | | | |
| | 32 cores (on 1 layer) | 30 cores (on 1 layer) | | | | | |
| | Copper ratio 7.1 | Copper ratio 7.5 | | | | | |
| Comparison | Wire used in | Wire used in | 1.2 | 1 | ppm | 65% | 90% |
| Example G | comparison example 7 | comparison example 5 | | | | | |
| | 34 cores (on 1 layer) | 30 cores (on 1 layer) | | | | | |
| | Copper ratio 6.7 | Copper ratio 7.5 | | | | | |
| Comparison | Wire used in | Wire used in | 1.2 | 4 | ppm | 55% | 87% |
| Example H | comparison example 8 | comparison example 6 | | | | | |
| | 36 cores (on 1 layer) | 32 cores (on 1 layer) | | | | | |
| | Copper ratio 6.7 | Copper ratio 7.1 | | | | | |
| Comparison | Wire used in | Wire used in | 1.2 | 0.6 | ppm | 65% | 94% |
| Example I | comparison example 9 | comparison example 6 | | | | | |
| | 38 cores (on 1 layer) | 32 cores (on 1 layer) | | | | | |
| | Copper ratio 5.9 | Copper ratio 7.1 | | | | | |

TABLE 4
Shape of NMR-simulated Superconducting Coil

| | | Main | | Upper and | Middle |
|---|---|---|---|---|---|
| Item | Unit | Coil | Outer Coil | Lower Sub-coils | Sub-coil |
| Bore | mm | 81 | 154.7 | — | — |
| Diameter | | | | | |
| Winding Inner | mm | 89 | 163 | 204 | 204 |
| Diameter | | | | | |
| Winding | mm | 149 | 193 | 223 | 214 |
| Outer | | | | | |
| Diameter | | | | | |
| Axial Length | mm | 400 | 400 | 128 | 89 |
| Winding | mm | 30 | 15 | 9.3 | 4.7 |
| Thickness | | | | | |
| Coil Outer | mm | 154 | 179 | 238 | 238 |
| Diameter | | | | | |

1. A superconducting multi-core billet comprised of a copper or copper alloy bullet of circular cross-section having a plurality of vertical holes made therein filled with superconducting material comprised of niobium-titanium (NbTi),
wherein
a copper-volume ratio, which is a ratio of said copper or said copper alloy therein to niobium-titanium therein in volume, is not smaller than four;
said plurality of vertical holes are made in said billet so that each of said vertical holes will be arrayed at an equal spacing on each of two inner and outer layers of concentric circles each of which is concentric with respect to the center of said billet;
the number of said vertical holes on said outer layer concentric circle N₁ is an even number not smaller than 16 and not larger than 38;
the number of said vertical holes on said inner layer concentric circle N₂ is a number defined as N₁/2, N₁/4, or N₁/8; and
the position of said vertical hole on said inner layer concentric circle is the angular-midpoint between the positions of the adjacent vertical holes on said outer layer concentric circle.

2. The superconducting multi-core billet according to claim 1, wherein said number of said vertical holes on said inner layer concentric circle N₂ is a prime number.

3. A superconducting multi-core billet comprised of a copper or copper alloy billet of circular cross-section having a plurality of vertical holes made therein filled with superconducting material comprised of niobium-titanium (NbTi),
a copper-volume ratio, which is a ratio of said copper or said copper alloy therein to niobium-titanium therein in volume, is not smaller than four;
said plurality of vertical holes are made in said billet so that each of said vertical holes will be arrayed at an equal spacing on one layer of concentric circle that is concentric with respect to the center of the billet; and
the number of said vertical holes on said concentric circle N is not smaller than 16 and not larger than 57.

4. The superconducting multi-core billet according to claim 3, wherein said number of the vertical holes N is a prime number or N is 33, 35, or 36.

5. A method for manufacturing a superconducting multi-core wire, comprising the steps of:
boring a plurality of vertical holes in a copper or copper alloy billet of circular cross-section;
inserting a round niobium-titanium rod into said vertical holes;
vacuum-sealing both ends of said vertical holes with metallic lids; and
applying hot extrusion process to said vacuum-sealed billet having the round niobium-titanium rod inserted therein followed by repeated application of drawings and heat treatments, wherein
a copper-volume ratio, which is a ratio of said copper or said copper alloy therein to niobium-titanium therein in volume, is not smaller than four;
said plurality of vertical holes are made in said billet so that each of said vertical holes will be arrayed at an equal spacing on each of two inner and outer layers concentric circles each of which is concentric with respect to the center of said billet;
the number of the vertical holes on the outer layer concentric circle N₁ is an even number not smaller than 16 and not larger than 38;
the number of the vertical holes on said inner layer concentric circle N₂ is a number defined as N₁/2, N₁/4, or N₁/8; and
the position of said vertical hole on said inner layer concentric circle is the angular-midpoint between the positions of the adjacent vertical holes on said outer layer concentric circle.

6. The method for manufacturing a superconducting multi-core wire according to claim 5, wherein the number of said vertical holes on said inner layer concentric circle N₂ is a prime number.

7. A method for manufacturing a superconducting multi-core wire, comprising the steps of:
boring a plurality of vertical holes in a copper or copper alloy billet of circular cross-section;
inserting a round niobium-titanium rod into said vertical holes;
vacuum-sealing both ends of said vertical holes with metallic lids; and
applying hot extrusion to said vacuum-sealed billet having said round niobium-titanium rod inserted therein followed by repeated application of drawings and heat treatments, wherein
a copper-volume ratio, which is a ratio of the copper or the copper alloy therein to niobium-titanium therein in volume, is not smaller than four;
said plurality of vertical holes are made in said billet so that each of said vertical holes will be arrayed at an equal spacing on one layer of concentric circle that is concentric with respect to the center of said billet; and
the number of said vertical holes on said concentric circle N is not smaller than 16 and not larger than 57 or N is 33, 35, or 39.

8. The method for manufacturing a superconducting multi-core wire according to claim 7, wherein the number of said vertical holes N is a prime number or N is 33, 35, or 36.

9. A superconducting magnet that uses superconducting multi-core wire according to claim 5.

10. A superconducting magnet that uses superconducting multi-core wire according to claim 6.

11. A superconducting magnet that uses superconducting multi-core wire according to claim 7.

12. A superconducting magnet that uses superconducting multi-core wire according to claim 8.
